(19) United States
(12) Patent Application Publication
(10) Pub. No.: US 2006/0102383 A1
(43) Pub. Date: May 18, 2006

(54) Method of fabricating high density printed circuit board

(75) Inventors: Hye Yeon Cha, Gyeongsangnam-do (KR); Byung Kook Sun, Seoul (KR); Tae Hoon Kim, Daejeon (KR); Jee Soo Mok, Cheongju-si (KR)

Correspondence Address: DARBY & DARBY P.C., P. O. BOX 5257, NEW YORK, NY, 10150-5257, US

(73) Assignee: Samsung Electro-Mechanics Co., Ltd., Kyunggi-do (KR)

(21) Appl. No.: 11/055,190

(22) Filed: Feb. 10, 2005

(30) Foreign Application Priority Data
Nov. 15, 2004 (KR) 2004-93182

(51) Int. Cl. H05K 3/12; H05K 1/11

(52) U.S. Cl. 174/255; 174/262; 174/258; 29/846

(57) ABSTRACT

Disclosed is a method of fabricating a high density PCB. Electric properties of a high frequency package product are reduced due to an increased length of a circuit even though the increased length of the circuit is necessary to maintain physical strength in the course of fabricating the PCB. Accordingly, a core insulating layer is removed, thereby providing a method of fabricating a slim PCB having a short wiring length.

### INCORPORATION BY REFERENCE

The present application claims priority under 35 U.S.C. §119 to Korean Patent Application No. 2004-93182 filed on Nov. 15, 2004. The content of the application is incorporated herein by reference in its entirety.

### BACKGROUND OF THE INVENTION

1. Field of the Invention

The present invention relates to a method of fabricating a high density printed circuit board (PCB). More particularly, the present invention pertains to a method of fabricating a slim PCB having a short wiring length. In the method, a core insulating layer is removed, thereby avoiding reduced electric properties of a high frequency package product due to an increased length of a circuit even though the increased length of the circuit is necessary to maintain physical strength in the course of fabricating the PCB.

2. Description of the Prior Art

Recently, it has been believed that reduction of the thickness of a substrate is essential to reduce thicknesses of parts constituting informatization devices, such as mobile phones. Furthermore, in current SiP (system in package) fields, it is known as the most sophisticated technology to reduce a thickness of a chip while not bending a wafer and to employ a small space.

In accordance with the trend of multi-functionalization and miniaturization of PCBs, demand for highly dense and miniaturized PCBs having a high speed is growing.

FIGS. 1a to 1m are sectional views stepwisely illustrating the fabrication of a six-layered PCB in the conventional build-up manner. In the specification of the present invention, the term “build-up manner” means a process which comprises forming internal layers and layering external layers one by one on the internal layers.

FIG. 1a is a sectional view of an unprocessed copper clad laminate (CCL) 101. Copper foils 102 are applied onto an insulating layer 103. Generally, the copper clad laminate acts as a substrate of a PCB, and means a thin laminate consisting of the insulating layer onto which copper is thinly applied.

The copper clad laminate is classified into a glass/epoxy CCL, a heat-resistant resin CCL, a paper/phenol CCL, a high-frequency CCL, a flexible CCL (polyimide film), a complex CCL and the like, in accordance with its use. Of them, the glass/epoxy CCL is most frequently used to fabricate double-sided PCBs and multilayer PCBs.

The glass/epoxy CCL consists of a reinforcing base substance in which an epoxy resin (combination of a resin and a hardening agent) is penetrated into a glass fiber, and a copper foil. The glass/epoxy CCL is graded FR-1 to FR-5, as prescribed by the National Electrical Manufacturers Association (NEMA), in accordance with the kind of reinforcing base substance and heat resistance. Traditionally, the FR-4 grade of glass/epoxy CCL is most frequently used, but recently, the demand for the FR-5 grade of glass/epoxy CCL, which has improved glass transition temperature (Tg), is growing.

In FIG. 1b, the copper clad laminate 101 is drilled to form a via hole 104 for interlayer connection.

In FIG. 1c, electroless copper plating and electrolytic copper plating processes are conducted. In this regard, the electroless copper plating process is conducted before the electrolytic copper plating process. The reason that the electroless copper plating process is conducted before the electrolytic copper plating process is that the electrolytic copper plating process using electricity is not possible on the insulating layer. In other words, the electroless copper plating process is conducted as a pretreatment process to form a thin conductive film needed to conduct the electrolytic copper plating process. Since it is difficult to conduct the electroless copper plating process and to assure economic efficiency, it is preferable that a conductive part of a circuit pattern be formed using the electrolytic copper plating process.

Subsequently, a paste 106 is packed in the via hole 104 so as to protect electroless and electrolytic copper plating layers 105 formed on a wall of the via hole 104. The paste is generally made of an insulating ink material, but may be made of a conductive paste according to the intended use of the PCB. The conductive paste includes a mixture of any one metal, which is selected from Cu, Ag, Au, Sn, Pb, or an alloy thereof and acts as a main component, and an organic adhesive. However, the plugging process of the via hole 104 using the paste may be omitted according to the purpose of the PCB.

In FIG. 1c, for convenience of understanding, the electroless and electrolytic copper plating layers 105 are illustrated as one layer without distinguishing two layers from each other.

In FIG. 1d, an etching resist pattern 107 is constructed to form a circuit pattern for an internal circuit.

A circuit pattern, which is printed on an artwork film, must be transcribed on the substrate so as to form the resist pattern. The transcription may be conducted through various methods, but the most frequently used method is to transcribe a circuit pattern, which is printed on an artwork film, onto a photosensitive dry film using ultraviolet rays. Recently, a liquid photo resist (LPR) is sometimes used instead of the dry film.

The dry film or LPR to which the circuit pattern is transferred acts as the etching resist 107, and when the substrate is dipped in an etching liquid as shown in FIG. 1e, the circuit pattern is formed.

After the formation of the circuit pattern, the appearance of the circuit pattern is observed using an automatic optical inspection (AOI) device so as to evaluate whether an internal circuit is correctly formed or not, and the resulting substrate is subjected to a surface treatment, such as a black oxide treatment.

The AOI device is used to automatically inspect the appearance of a PCB. The device automatically inspects the appearance of the PCB employing an image sensor and a pattern recognition technology using a computer. After reading information regarding the pattern of an objective circuit using the image sensor, the AOI device compares the information to reference data to evaluate whether defects have occurred or not.

The minimum value of an annular ring of a land (a portion of the PCB on which parts are to be mounted) and a ground state of a power source can be inspected by use of the AOI device. Furthermore, the width of the circuit pattern can be measured and the omission of a hole can be detected. However, it is impossible to inspect the internal state of a hole.

The black oxide treatment is conducted so as to improve adhesion strength and heat resistance before an internal layer having the circuit pattern is attached to an external layer.

In FIG. 1f, resin-coated copper (RCC) is applied to both sides of the resulting substrate. The RCC consists of a substrate in which a copper foil 109 is formed on only one side of a resin layer 108, and the resin layer 108 acts as an insulator between the circuit layers.

In FIG. 1g, a blind via hole 110 is formed to electrically connect the internal and external layers to each other. The blind via hole may be mechanically drilled. However, it is necessary to more precisely conduct the drilling in comparison with processing of a through hole, and thus, it is preferable to use an yttrium aluminum garnet (YAG) laser or a CO₂ laser. The YAG laser can drill both a copper foil and an insulating layer, but the CO₂ laser can drill only the insulating layer.

In FIG. 1h, an external layer 111 is laminated according to a plating process.

In FIG. 1i, the external layer 111 formed as shown in FIG. 1h is patterned according to the same procedure as the formation of the circuit pattern of the internal layer. The patterned external layer 111 is then inspected in terms of the circuit and subjected to a surface treatment, as in the case of the circuit pattern of the internal layer.

In FIG. 1j, additional RCC is applied to both sides of the resulting substrate. This RCC includes a resin layer 112 and a copper foil 113 coated on one side of the resin layer 112, and the resin layer 112 acts as an insulator.

In FIG. 1k, a blind via hole 114 is formed to electrically connect the external layers to each other using the laser as described above.

In FIG. 1l, the additional external layer 115 is laminated according to a plating process.

In FIG. 1m, the additional external layer 115 is patterned according to the same procedure as the external layer 111, and the circuits of the patterned external layer 115 are then inspected and the layer is subjected to a surface treatment.

The number of layers constituting the multilayer PCB may be continuously increased by repeating the lamination of layers, the construction of the circuit patterns, the inspection of the circuit patterns, and the surface treatment of the resulting structure.

Subsequently, a photo-solder resist and an Ni/Au layer are formed on the resulting circuit pattern, thereby creating a six-layered PCB.

The conventional build-up manner cannot meet recent demands because of a limit in reducing a thickness of a substrate. In other words, a conventional CCL including an insulating core, in which a resin is incorporated in a glass fiber, inevitably has some thickness. However, even though the insulating core of the CCL serves to maintain strength during the fabrication process, electric properties are reduced due to an increased length of a circuit.

With respect to this, U.S. Pat. No. 6,696,764 discloses a method of fabricating two PCBs by cutting a central part of the PCB through a mechanical process after construction of the PCB. However, since the cutting is mechanically conducted, it has a limit to be applied to the fabrication of a precise PCB. Additionally, a core insulating layer remains after the cutting, making the PCB thick. Accordingly, a more fundamental alternative proposal is needed to reduce a thickness of the PCB.

### SUMMARY OF THE INVENTION

Therefore, the present invention has been made keeping in mind the above disadvantages of a conventional method of fabricating a PCB, and an object of the present invention is to provide a novel method of fabricating a PCB, in which it is possible to remove an insulating core having an undesired thickness.

The above object can be accomplished by providing a method of fabricating a high density PCB. The method comprises applying an insulator, which is capable of being patterned by ultraviolet rays, on one side of a copper foil; patterning the insulator using the ultraviolet rays; forming a first circuit pattern on the insulator by electrolytic plating; laminating an insulating layer on the first circuit pattern; and forming via holes and second circuit patterns on the insulating layer and the other side of the copper foil.

Additionally, the present invention provides a method of fabricating a high density PCB. The method comprises applying an insulator, which is capable of being patterned by ultraviolet rays, on one side of a copper foil; patterning the insulator using the ultraviolet rays; forming a first circuit pattern on the insulator by electrolytic plating; forming a second circuit pattern on the copper foil; laminating insulating layers on both sides of a resulting structure; and forming via holes and third circuit patterns on the insulating layers and the other side of the copper foil.

Furthermore, the present invention provides a high density PCB, which comprises an insulator which is patterned by ultraviolet rays and has first circuit patterns formed on both sides thereof. A plurality of insulating layers is laminated on the insulator, and a plurality of first via holes is formed through the insulating layers. Circuit layers are interposed between the plurality of insulating layers, and a plurality of second via holes and second circuit patterns are formed in the circuit layers.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1m are sectional views stepwisely illustrating the fabrication of a six-layered PCB in the conventional build-up manner;

FIGS. 2a to 2n illustrate the fabrication of a PCB according to the first embodiment of the present invention;

FIGS. 3a to 3m illustrate the fabrication of a PCB according to the second embodiment of the present invention; and

FIGS. 4a to 4f illustrate the fabrication of a PCB according to the third embodiment of the present invention.

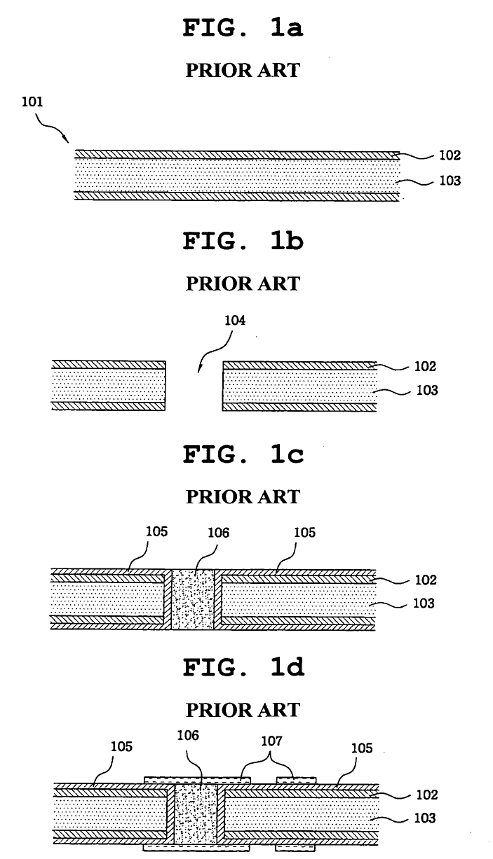

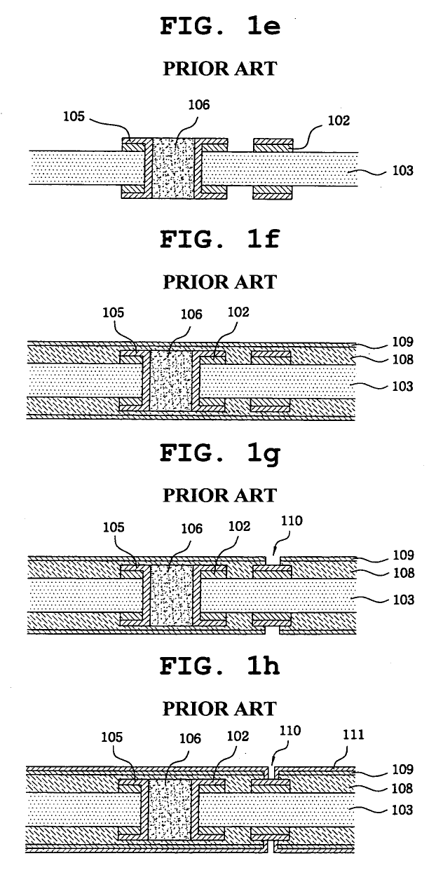

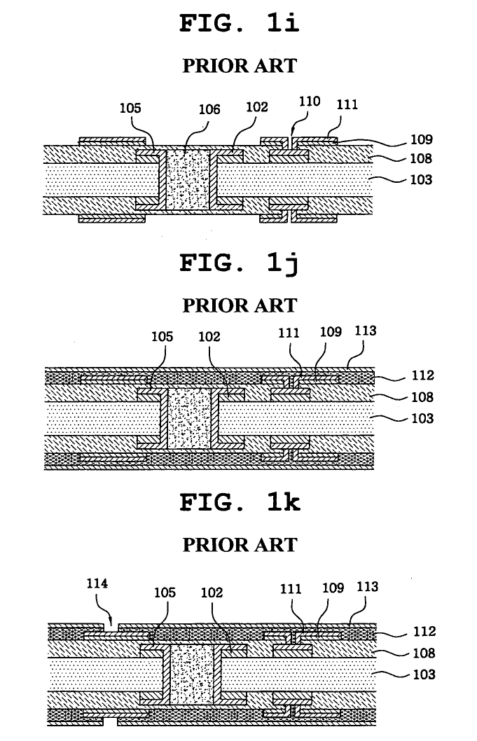

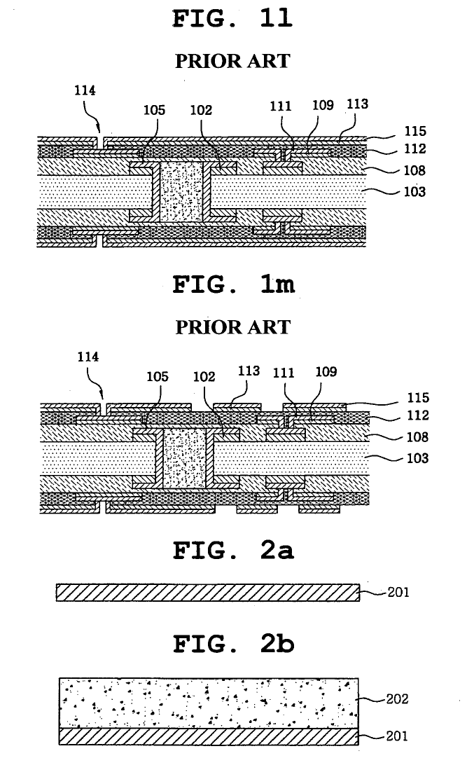

### DETAILED DESCRIPTION OF THE INVENTION

Hereinafter, the present invention will be described in detail with reference to the drawings.

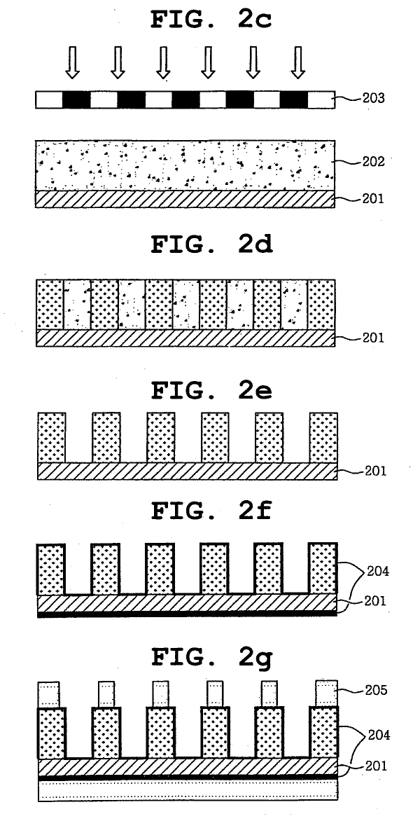

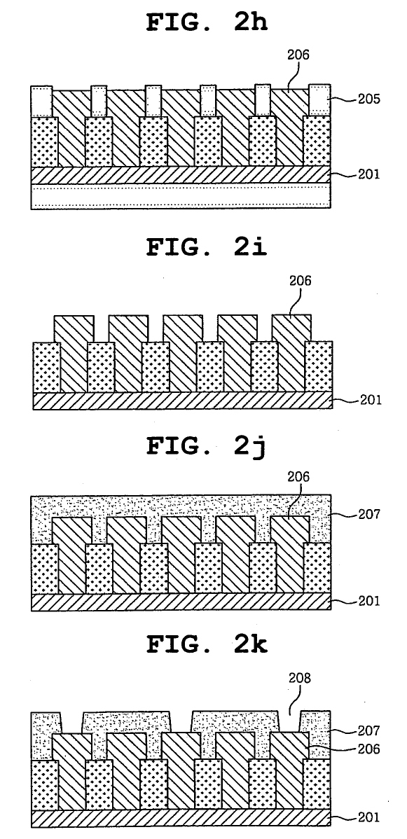

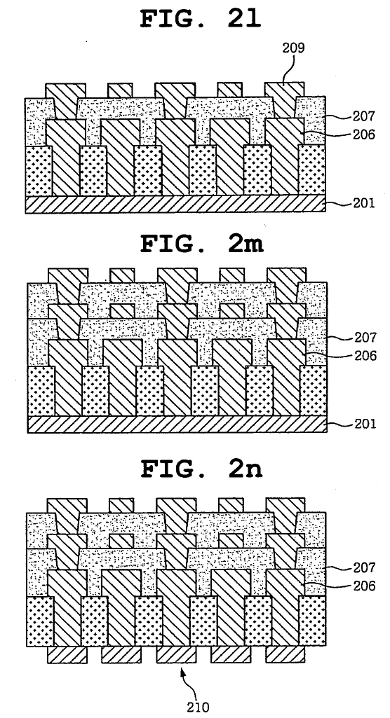

FIGS. 2a to 2n illustrate the fabrication of a PCB according to the first embodiment of the present invention.

FIG. 2a illustrates a sectional view of a copper foil 201. The copper foil 201 is the same as a copper foil which is laminated on a typical CCL, and it is preferable that a thickness of the copper foil 201 be about 9-12 μm.

In FIG. 2b, an insulator 202, which is capable of being patterned by ultraviolet rays, is applied on one side of the copper foil 201. Capable of being patterned by ultraviolet rays, the insulator is a polymer which contains an acrylic group and thus has a property in which it is hardened through a polymerization reaction by the irradiation of ultraviolet rays. Preferably, examples of a material having the above property include benzocyclobutene (BCB) as an ultraviolet sensitive polymer or SU-8 as a negative photoresist. Furthermore, it is preferable that the insulator 202 have chemical resistance and heat resistance so as to withstand subsequent chemical and heat treatments.

In FIG. 2c, a glass mask 203, on which a predetermined pattern is formed, is applied to the insulator 202, and ultraviolet rays are then irradiated to achieve development of the pattern.

As shown in FIG. 2d, ultraviolet rays are not passed through a portion of the insulator 202, which corresponds in position to a black portion of the glass mask 203, and thus does not harden the portion of the insulator. However, the other portion of the insulator 202, which corresponds in position to a transparent portion of the glass mask 203, is polymerized by ultraviolet rays and thus hardened.

After the patterning is conducted, baking may be selectively conducted to assure desired stiffness of the insulator 202.

In FIG. 2e, if an unhardened portion of the insulator 202 is selectively removed, the insulator is patterned. The resulting substrate is immersed in a developing liquid to remove the unhardened portion of the insulator 202.

In FIG. 2f, a plating layer 204 is formed on the insulator 202 through an electroless plating process or a sputtering process. The plating layer 204 acts as a seed layer for subsequent electrolytic plating.

In FIG. 2g, a plating resist 205 is applied on both sides of the substrate, and a portion of the plating resist 205, which is applied on the patterned insulator 202, is exposed and developed to be patterned. A dry film may be used as the plating resist 205.

In FIG. 2h, a circuit pattern 206 is formed while spaces between walls of a pattern of the insulator 202 are filled by electrolytic plating. For convenience of understanding, the plating layer 204 for the seed layer is not shown in FIGS. 2h to 2n.

In FIG. 2i, the plating resist 205 is stripped. If the plating resist 205 is the dry film, the stripping may be conducted using NaOH or KOH.

Subsequently, the circuit pattern may be selectively subjected to a surface treatment process.

In FIG. 2j, an insulating layer 207 is laminated so as to assure interlayer insulation for additional lamination. A prepreg, which is used as an insulating layer in a typical process of fabricating a multilayered PCB, may be used as the insulating layer 207.

In FIG. 2k, the insulating layer 207 is drilled by a laser to form a blind via hole 208 at a predetermined position thereof.

In FIG. 2l, after a seed layer is formed on the insulating layer 207 through an electroless plating process, the via hole 208 is filled by electrolytic plating, and thus, a circuit pattern 209 is formed.

Next, as shown in FIG. 2m, lamination of the insulating layer and formation of the circuit pattern are repeated to form the desired number of circuit layers. The total number of circuit layers depends on the insulating layer and the circuit pattern.

As shown in FIG. 2n, a circuit pattern is formed on the other side 210 of the copper foil, thereby creating a 6-layered PCB. Formation of the circuit pattern is achieved by conducting the etching after an etching resist is applied and patterned.

In the method of fabricating a PCB according to the present invention, a central layer of the PCB consists of the insulating layer 207, such as prepreg, instead of a core insulating layer interposed between copper foils of a conventional CCL unlike a conventional multilayered PCB.

The core insulating layer constituting the conventional CCL is at least 60 μm or more in thickness, but the insulating layer 207, such as prepreg, is normally about 30 μm in thickness. Hence, the PCB of the present invention is much thinner than the conventional PCB.

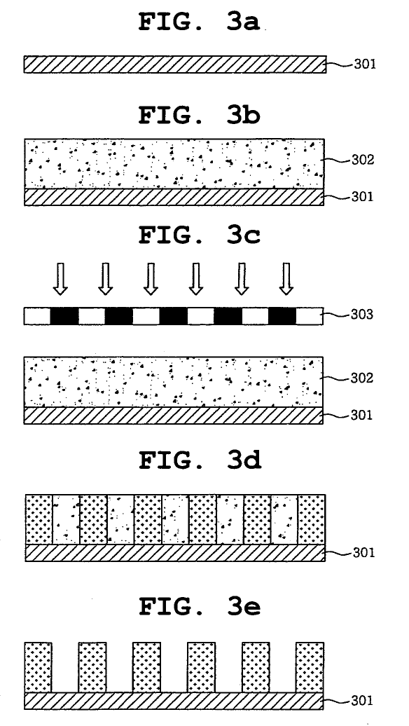

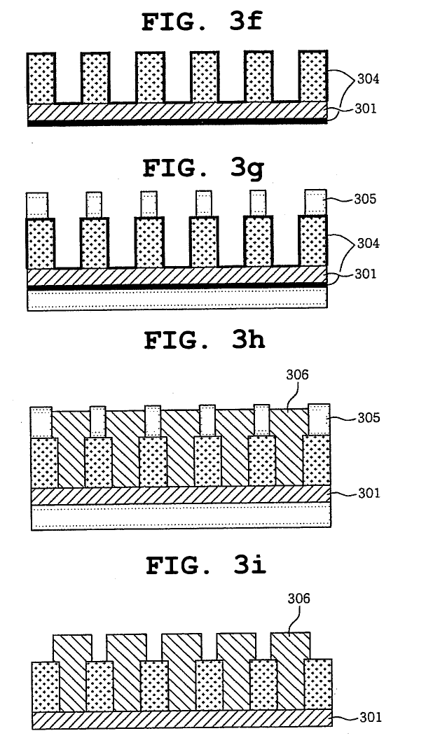

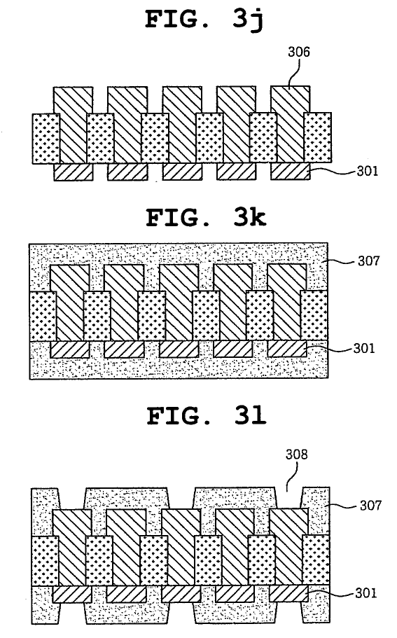

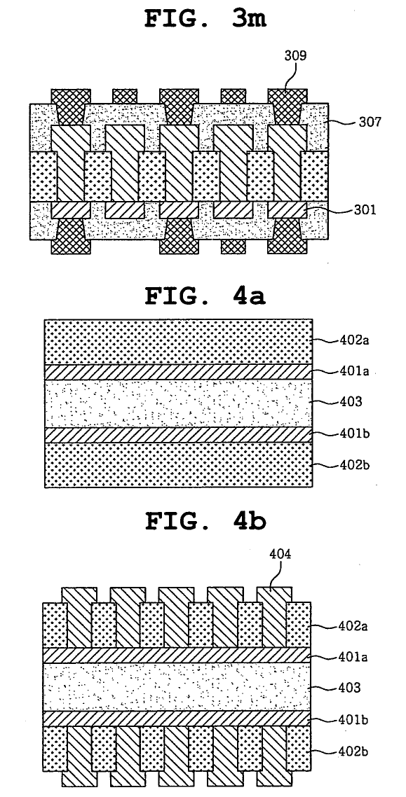

FIGS. 3a to 3m illustrate the fabrication of a PCB according to the second embodiment of the present invention.

The procedure of FIGS. 3a to 3i is the same as that of FIGS. 2a to 2i. In FIGS. 3a to 3i, reference numerals 301 to 306 correspond to reference numerals 201 to 206 of FIGS. 2a to 2f. For convenience of the understanding, a plating layer 304 for a seed layer is not shown in FIGS. 3h to 3m.

In FIG. 3j, a circuit pattern is formed on a copper foil 301. Formation of the circuit pattern may be achieved by etching a substrate after a predetermined etching resist pattern is formed.

In FIG. 3k, an insulating layer 307 is laminated so as to assure interlayer insulation for additional lamination. A prepreg, which is used as an insulating layer in a typical process of fabricating a multilayered PCB, may be used as the insulating layer 307.

In FIG. 3l, the insulating layer 307 is drilled by a laser to form a via hole 308 at a predetermined position thereof. It is possible to form the via hole through a mechanical drilling process, if necessary.

In FIG. 3m, after a seed layer is formed on the insulating layer 307 through an electroless plating process, the via hole 308 is filled by electrolytic plating, and thus, a circuit pattern 309 is formed.

Unlike in FIG. 2n, in a sectional view of the PCB of FIG. 3m, the insulating layers and the circuit layers are laminated on both sides of a central insulator 302 which is capable of being patterned by ultraviolet rays.

Lamination of the insulating layer and formation of the circuit pattern may be repeated to form the desired number of circuit layers. After the formation of the circuit pattern, it is preferable to conduct predetermined inspection and surface treatment processes.

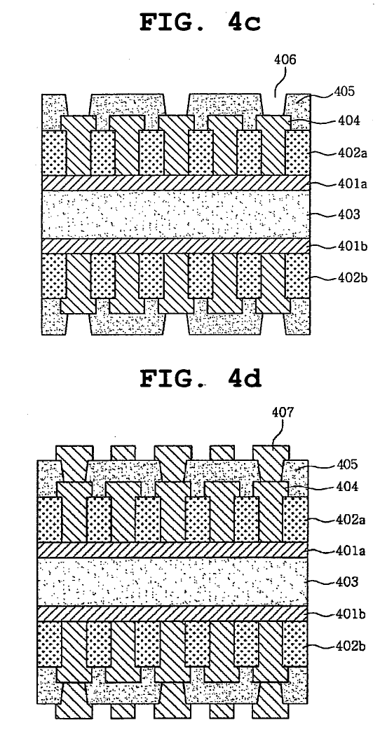

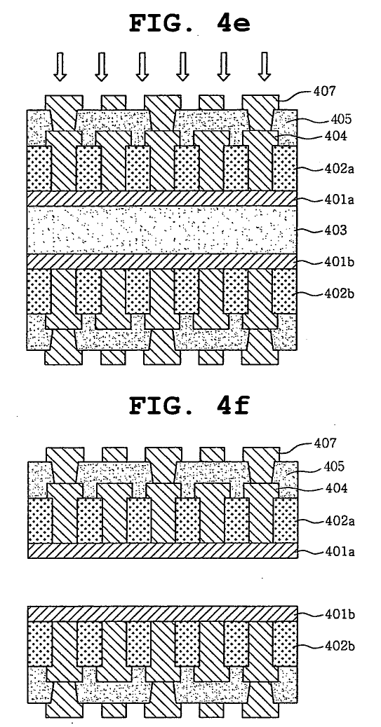

FIGS. 4a to 4f illustrate the fabrication of a PCB according to the third embodiment of the present invention.

As shown in FIG. 4a, insulators 402a, 402b, which are capable of being patterned by ultraviolet rays, are laminated on copper foils 401a, 401b, and the resulting structures are then attached to both sides of a double-sided adhesive sheet 403 so that the copper foils 401a, 401b face each other. The double-sided adhesive sheet 403 must be capable of being released or separated from the copper foils 401a, 401b using ultraviolet rays or heat.

In FIG. 4b, after the insulators 402 are exposed and developed by ultraviolet rays using a predetermined mask and thus patterned, a seed layer is formed by electroless plating, and a circuit pattern 404 is formed while spaces between walls of a pattern of the insulator 402 are filled by electrolytic plating.

In FIG. 4c, an insulating layer 405 is laminated so as to assure interlayer insulation for additional lamination, and drilled through laser or mechanical drilling processes to form a via hole 406.

In FIG. 4d, after a seed layer is formed on the insulating layer 405 by electroless plating, the via hole 406 is filled by electrolytic plating, and thus, a circuit pattern 407 is formed.

Next, lamination of the insulating layer and formation of the circuit pattern are repeated to form the desired number of circuit layers.

In FIG. 4e, the double-side adhesive sheet 403 is released from the copper foils 401a, 401b by applying ultraviolet rays or heat to the central part of the PCB.

As shown in FIG. 4f, the PCB is divided into two by the application of ultraviolet rays or heat, and the exposed copper foils 401a, 401b are subjected to an etching process and the like to form circuit patterns, thereby creating two PCBs that are the same as the PCB formed through a procedure of FIGS. 2a to 2n.

Unlike a conventional multilayered PCB, a central layer of the PCB according to the present invention consists of the insulating layer 405, such as prepreg, instead of a core insulating layer interposed between copper foils of a conventional CCL. Hence, the PCB of the present invention is much thinner than the conventional PCB.

As described above, the present invention provides a method of fabricating a high density PCB, in which a core insulating layer is removed, resulting in a very thin PCB.

Furthermore, in the method of fabricating the high density PCB according to the present invention, the core insulating layer is completely removed through exposure using ultraviolet rays instead of a mechanical cutting process, thereby reducing the thickness of the final PCB.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A method of fabricating a high density printed circuit board, comprising:
applying an insulator, which is capable of being patterned by ultraviolet rays, on one side of a copper foil;
patterning the insulator using the ultraviolet rays;
forming a first circuit pattern on the insulator by electrolytic plating;
laminating an insulating layer on the first circuit pattern; and
forming via holes and second circuit patterns on the insulating layer and the other side of the copper foil.

2. The method as set forth in claim 1, wherein the forming of the first circuit pattern comprises:
forming seed layers for electrolytic copper plating on both sides of the copper foil;
applying plating resists on both sides of the copper foil;
patterning a portion of the plating resists, which is applied on the patterned insulator;
forming the first circuit pattern by the electrolytic copper plating; and
stripping the plating resists.

3. A method of fabricating a high density printed circuit board, comprising:
applying an insulator, which is capable of being patterned by ultraviolet rays, on one side of a copper foil;
patterning the insulator using the ultraviolet rays;
forming a first circuit pattern on the insulator by electrolytic plating;
forming a second circuit pattern on the copper foil;
laminating insulating layers on both sides of a resulting structure; and
forming via holes and third circuit patterns on the insulating layers and the other side of the copper foil.

4. The method as set forth in claim 3, wherein the forming of the first circuit pattern comprises:
forming seed layers on both sides of the copper foil;
applying plating resists on both sides of the copper foil and patterning the applied plating resists;
forming the first circuit pattern by electrolytic copper plating; and
stripping the plating resists.

5. A method of fabricating a high density printed circuit board, comprising:
applying an insulator, which is capable of being patterned by ultraviolet rays, on one side of each of two copper foils;
attaching a double-sided adhesive sheet, which is capable of being released by the ultraviolet rays, between the two copper foils;
patterning the insulator using the ultraviolet rays;
forming a first circuit pattern on the insulator by electrolytic plating;
laminating an insulating layer on the first circuit pattern;
forming a via hole through the insulating layer and a second circuit pattern on the insulating layer; and
irradiating the ultraviolet rays onto the double-sided adhesive sheet to divide a resulting structure into two PCBs.

6. The method as set forth in claim 5, wherein the forming of the first circuit pattern comprises:
forming seed layers for electrolytic copper plating on the copper foils;
applying plating resists on the copper foils and patterning the applied plating resists;
conducting the electrolytic copper plating; and
stripping the plating resists.

7. A high density printed circuit board, comprising:
an insulator which is patterned by ultraviolet rays and has first circuit patterns formed on both sides thereof;
a plurality of insulating layers, which is laminated on the insulator and through which a plurality of first via holes is formed; and
circuit layers, which are interposed between the plurality of insulating layers and in which a plurality of second via holes and second circuit patterns are formed.
